(19) United States
(12) Patent Application Publication
(10) Pub. No.: US 2026/0143925 A1
(43) Pub. Date: May 21, 2026

(54) FLEXIBLE SUBSTRATE, DISPLAY APPARATUS USING THE FLEXIBLE SUBSTRATE, AND METHOD OF MANUFACTURING THE SAME

(71) Applicant: LG Display Co., Ltd., Seoul (KR)

(72) Inventors: Geum Young LEE, Paju-si (KR); Jeong Oh KIM, Paju-si (KR); Myung Jae YOO, Paju-si (KR); Jae Choul YU, Paju-si (KR); Se Yeon JUNG, Paju-si (KR)

(73) Assignee: LG Display Co., Ltd., Seoul (KR)

(21) Appl. No.: 19/333,931

(22) Filed: Sep. 19, 2025

(30) Foreign Application Priority Data
Nov. 15, 2024 (KR) 10-2024-0163456

(51) Int. Cl. H10K 59/123; H10K 59/121; H10K 59/131

(52) U.S. Cl. CPC H10K 59/123; H10K 59/121; H10K 59/131

(57) ABSTRACT

A flexible substrate, a display apparatus using the flexible substrate, and a method of manufacturing the same capable of preventing or suppressing surface damage to the flexible substrate during a process of separating a carrier substrate from the flexible substrate in the manufacture of a flexible display apparatus and capable of achieving an enhancement in yield are disclosed. The flexible substrate includes a first substrate layer made of a conductive material and having a plurality of first open portions, a second substrate layer disposed on the first substrate layer and having a plurality of contact holes, a third substrate layer disposed on the second substrate layer and electrically connected to the first substrate layer through the plurality of contact holes, the third substrate layer being made of a conductive material and having a plurality of second open portions, and a fourth substrate layer disposed on the third substrate layer.

This application claims the benefit of Korean Patent Application No. 10-2024-0163456, filed on Nov. 15, 2024, which is hereby incorporated by reference as if fully set forth herein.

### BACKGROUND

### Field of the Disclosure

The present disclosure relates to a display apparatus, and more particularly to a flexible substrate, a display apparatus using the flexible substrate, and a method of manufacturing the same which are capable of preventing or suppressing surface damage to the flexible substrate during a process of separating a carrier substrate from the flexible substrate, for manufacture of a flexible display apparatus, and capable of achieving an enhancement in yield.

### Discussion of the Related Art

Image display apparatuses, which render a variety of information on a screen, are core technologies of the information communication age, and are being developed toward further thinness, further lightness, greater portability, and higher performance. As such, display apparatuses, which may be manufactured to have a light and thin structure, are being highlighted.

As concrete examples of such a display apparatus, there are a liquid crystal display (LCD) apparatus, a quantum dot (QD) display apparatus, a field emission display (FED) apparatus, an organic light emitting diode (OLED) display apparatus, etc.

An OLED display apparatus includes, as a constituent element thereof, a light emitting diode including a cathode and an anode facing each other under the condition that an organic emission layer is interposed therebetween. As holes and electrons respectively injected from the cathode and the anode into the organic emission layer are coupled to each other in the organic emission layer, light is emitted and, as such, an image is displayed.

Thus, the OLED display apparatus is a self-luminous display apparatus and, as such, is not only advantageous in terms of power consumption according to low-voltage driving, but also has excellent color rendering, fast response time, wide viewing angle, and high contrast ratio (CR). In this regard, the OLED display apparatus is being highlighted as a next generation display apparatus and research thereon is being conducted.

Meanwhile, in recent years, demand for a flexible display apparatus using a flexible substrate, such as a plastic substrate, has increased. Such a flexible display apparatus has advantages of a large-screen display and easy portability because the flexible display apparatus is portable in a folded state and displays an image in an unfolded state.

Since such a plastic substrate has flexible characteristics, it is difficult to use the plastic substrate itself in a process of manufacturing a display apparatus. For this reason, the process is performed under the condition that the plastic substrate is attached to one surface of a carrier substrate, such as a glass substrate. After completion of the process, the carrier substrate is separated from the plastic substrate and, as such, a display apparatus is manufactured.

Separation of the carrier substrate from the plastic substrate is carried out through laser irradiation. For this reason, there is a potential problem in that the surface of the plastic substrate may be damaged.

Furthermore, laser irradiation may be non-uniform, or energy may be locally concentrated. As a result, an impact may be generated during substrate separation and, as such, damage to one or more elements of the display apparatus may occur. Accordingly, there is a potential problem in that yield may be degraded.

### SUMMARY

Accordingly, the present disclosure is directed to a flexible substrate, a display apparatus using the flexible substrate, and a method of manufacturing the same that substantially obviate one or more problems due to limitations and disadvantages of the related art.

It is an object of the present disclosure to provide a display apparatus and a method of manufacturing the same which are capable of preventing or suppressing surface damage to a flexible substrate during a process of separating a carrier substrate from the flexible substrate, for manufacture of a flexible display apparatus.

It is another object of the present disclosure to provide a display apparatus and a method of manufacturing the same which are capable of preventing or suppressing surface damage to a flexible substrate during a process of separating a carrier substrate from the flexible substrate, thereby achieving an enhancement in yield.

Objects of the present disclosure are not limited to the above-described object, and other objects of the present disclosure will be more clearly understood by those skilled in the art from the following detailed description.

In accordance with an aspect of the present disclosure, a flexible substrate includes a first substrate layer made of a conductive material and having a plurality of first open portions, a second substrate layer disposed on the first substrate layer and having a plurality of contact holes, a third substrate layer disposed on the second substrate layer and electrically connected to the first substrate layer through the plurality of contact holes, the third substrate layer being made of a conductive material and having a plurality of second open portions, and a fourth substrate layer disposed on the third substrate layer.

In accordance with another aspect of the present disclosure, a display apparatus includes a flexible substrate according to an embodiment of the present disclosure, a thin film transistor on the flexible substrate, an organic light emitting diode connected to the thin film transistor, and an encapsulation film disposed on the organic light emitting diode.

In accordance with yet another aspect of the present disclosure, a method of manufacturing a display apparatus includes forming a separation layer on a carrier substrate, forming, on the separation layer, a first substrate layer made of a conductive material and having a plurality of first open portions, forming, on the first substrate layer, a second substrate layer having a plurality of contact holes, forming, on the second substrate layer, a third substrate layer electrically connected to the first substrate layer through the plurality of contact holes and made of a conductive material, the third substrate layer having a plurality of second open portions. forming a fourth substrate layer on the third substrate layer, sequentially forming, on the fourth substrate layer, a pixel layer with a thin film transistor and a light emitting diode and an encapsulation film, and separating the carrier substrate by applying a voltage or current to the third substrate layer such that the first substrate layer generates heat.

Detailed matters of other example embodiments are included in the following detailed description and the accompanying drawings.

In accordance with example embodiments of the present disclosure, the carrier substrate is separated from the flexible substrate under the condition that the first substrate layer generates heat. Accordingly, the flexible substrate is free from foreign matter of the carrier substrate or scratches of the carrier substrate.

Since the carrier substrate is separated from the flexible substrate under the condition that the first substrate layer generates heat, it may be possible to prevent or suppress damage to the surface of the flexible substrate and to prevent or suppress damage to elements caused by impact generated during separation of the carrier substrate from the flexible substrate.

In addition, the first and third substrate layers may be used as a heat dissipation plate of the display apparatus.

Effects according to the example embodiments of the present disclosure are not limited to the above-illustrated content, and wider variety of additional effects may be included in or learned from the practice of the present disclosure.

### BRIEF DESCRIPTION OF THE DRAWINGS

The accompanying drawings, which are included to provide a further understanding of the present disclosure and are incorporated in and constitute a part of this application, illustrate example embodiment(s) of the present disclosure and along with the description serve to explain the principle of the disclosure. In the drawings:

FIG. 1 is a schematic cross-sectional view of a flexible display apparatus according to an example embodiment of the present disclosure;

FIG. 2 is a schematic cross-sectional view showing an example of a display panel of the flexible display apparatus according to an example embodiment of the present disclosure;

FIG. 3 is a cross-sectional view showing a flexible substrate according to an example embodiment of the present disclosure;

FIG. 4A is a plan view of a second transparent electrode layer according to a first example embodiment of the present disclosure;

FIG. 4B is a plan view of a first transparent electrode layer according to the first example embodiment of the present disclosure;

FIG. 5A is a plan view of a second transparent electrode layer according to a second example embodiment of the present disclosure;

FIG. 5B is a plan view of a first transparent electrode layer according to the second example embodiment of the present disclosure;

FIG. 6A is a plan view of a second transparent electrode layer according to a third example embodiment of the present disclosure;

FIG. 6B is a plan view of a first transparent electrode layer according to the third example embodiment of the present disclosure;

FIG. 7A is a plan view of a second transparent electrode layer according to a fourth example embodiment of the present disclosure;

FIG. 7B is a plan view of a first transparent electrode layer according to the fourth example embodiment of the present disclosure;

FIG. 8A is a plan view of a second transparent electrode layer according to a fifth example embodiment of the present disclosure;

FIG. 8B is a plan view of a first transparent electrode layer according to the fifth example embodiment of the present disclosure;

FIG. 9A is a plan view of a second transparent electrode layer according to a sixth example embodiment of the present disclosure;

FIG. 9B is a plan view of a first transparent electrode layer according to the sixth example embodiment of the present disclosure;

FIG. 10A is a plan view of a second transparent electrode layer according to a seventh example embodiment of the present disclosure;

FIG. 10B is a plan view of a first transparent electrode layer according to the seventh example embodiment of the present disclosure; and

FIG. 11 is a cross-sectional view explaining a method of manufacturing a display apparatus in accordance with an example embodiment of the present disclosure.

### DETAILED DESCRIPTION

Hereinafter, example embodiments of the present disclosure will be described in detail with reference to the accompanying drawings. Throughout the present disclosure, the same reference numerals designate the same constituent elements, respectively.

In the following description of the present disclosure, a detailed description of known technologies or configurations incorporated herein may be omitted where it may obscure the subject matter of the present disclosure. Furthermore, the following terms associated with constituent elements are selected taking into consideration ease of preparation of the disclosure, and may differ from the names of the corresponding elements in practice.

The shape, size, ratio, angle, number and the like shown in the drawings to illustrate the example embodiments of the present disclosure are only for illustration and are not limited to the contents of the drawings. Wherever possible, the same reference numbers will be used throughout the drawings to refer to the same or like parts.

In the following description, detailed descriptions of known technologies related to the present disclosure may be omitted so as not to unnecessarily obscure the subject matter of the present disclosure.

Where terms such as “including”, “having”, and “comprising” are used throughout the specification, an additional component may be present, unless a more limiting term like “only” is used. A component described in a singular form encompasses components in a plural form, and vice versa, unless particularly stated otherwise.

It should be interpreted that the components included in the example embodiments of the present disclosure include an error range, although there is no additional particular description thereof.

In describing a variety of embodiments of the present disclosure, where terms for a positional relationship such as “on”, “above”, “under” and “next to” are used, at least one intervening element may be present between two elements unless a more limiting term like “immediately” or “directly” is used.

In describing a variety of embodiments of the present disclosure, where a temporal relationship is described, for example, where terms for temporal relationship of events such as “after”, “subsequently”, “next”, and “before” are used, there may also be the case in which the events are not continuous, unless a more limiting term like “immediately” or “directly” is used.

In the meantime, although terms including an ordinal number, such as first or second, may be used to describe a variety of constituent elements, the constituent elements are not limited to the terms, and the terms are used only for the purpose of discriminating one constituent element from other constituent elements. Accordingly, a first constituent element may represent a second constituent element, and vice versa, within the scope of the present disclosure unless particularly stated otherwise.

The respective features of various example embodiments according to the present disclosure can be partially or entirely joined or combined and technically variably related or operated, and the embodiments can be implemented independently or in combination.

Hereinafter, a display apparatus according to example embodiments of the present disclosure will be described with reference to the accompanying drawings.

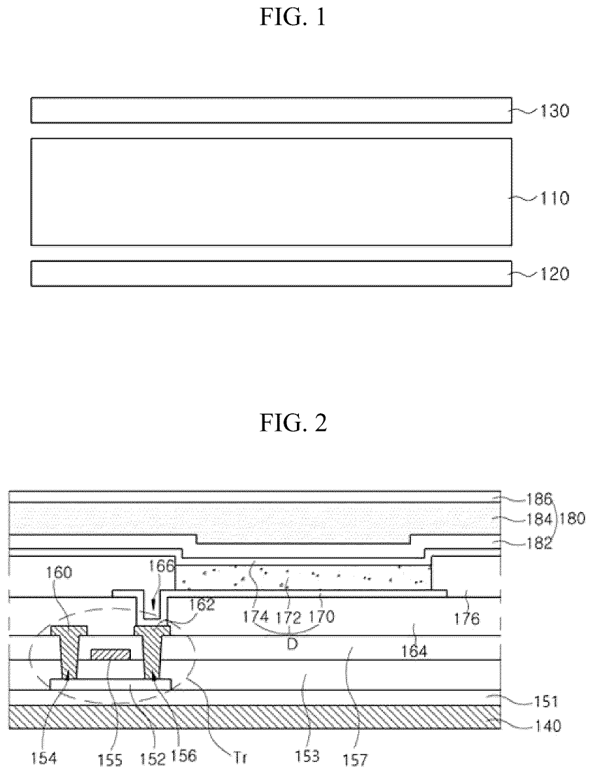

FIG. 1 is a schematic cross-sectional view of a flexible display apparatus according to an example embodiment of the present disclosure. FIG. 2 is a schematic cross-sectional view showing an example of a display panel of the flexible display apparatus according to an example embodiment of the present disclosure.

As shown in FIGS. 1 and 2, the display apparatus according to the example embodiment of the present disclosure may include a display panel 110, a back plate 120 disposed under the display panel 110, and a cover window 130 disposed over the display panel 110.

The cover window 130 may be constituted by a reinforced glass or a plastic film having impact resistance and light transparency to protect the display panel 110 from external impact, moisture, heat, etc. The cover window 130 may be formed to have a thickness of 30 to 200 μm to satisfy strength characteristics and folding characteristics.

When the cover window 130 is constituted by the plastic film, the plastic film may include a polyimide (PI) film, a polyethylene terephthalate (PET) film, a polypropylene glycol (PPG) film, a polycarbonate (PC) film, or the like, without being limited thereto.

When the cover window 130 is made of the reinforced glass, the cover window 130 may be broken by external force or stress. To prevent or suppress fragments of the cover window 130 from scattering in this case, an anti-scattering film may be attached to an upper surface of the cover window 130. The anti-scattering film may include, for example, a base film including polyethylene terephthalate (PET), colorless polyimide (CPI), a laminate of polyethylene terephthalate (PET) and colorless polyimide (CPI), or the like. A hard coating layer, an anti-reflection layer, an anti-fingerprint layer, etc. may be coated on an upper surface of the base film.

The display panel 110 may include an active area in which a plurality of pixels is disposed to display an image, and a non-active area disposed around the active area to surround the active area. The non-active area may include a pad part to which an external driving module is coupled.

The display panel 110 may be a flexible display panel including a plurality of pixels formed on a flexible substrate. The display panel 110 may be an organic light emitting diode panel.

The back plate 120 may be constituted by a polymer film. The polymer film usable for the back plate 120 may be made of polyimide (PI), polyethylene terephthalate (PET), polycarbonate (PC), or polyethylene naphthalate (PEN), without being limited thereto.

As shown in FIG. 2, the display panel 110 according to the embodiment of the present disclosure may include a flexible substrate 140, a thin film transistor Tr disposed on the flexible substrate 140, a light emitting diode D disposed over the flexible substrate 140 and connected to the thin film transistor Tr, and an encapsulation film 180 configured to cover the light emitting diode D.

The flexible substrate 140 has a multilayer structure. This will be described later in detail.

A multi-buffer layer 151 may be formed on the flexible substrate 140. The multi-buffer layer 151 may be configured through stacking of an inorganic insulating material such as silicon oxide or silicon nitride to form a multilayer structure. The multi-buffer layer 151 may be omitted.

The thin film transistor Tr may be formed on the multi-buffer layer 151. For example, a semiconductor layer 1152 may be formed on the multi-buffer layer 151. The semiconductor layer 152 may be made of an oxide semiconductor material or polycrystalline silicon. When the semiconductor layer 152 is made of an oxide semiconductor material, a light shielding pattern (not shown) may be formed under the semiconductor layer 152. The light shielding pattern prevents or suppresses incidence of light upon the semiconductor layer 152, thereby preventing or protecting the semiconductor layer 152 from being degraded due to light. On the other hand, the semiconductor layer 152 may be made of polycrystalline silicon. In this case, opposite edges of the semiconductor layer 152 may be doped with impurities.

A gate insulating layer 153 made of an insulating material is formed on the semiconductor layer 152. The gate insulating layer 153 may be made of an inorganic insulating material such as silicon oxide or silicon nitride.

A gate electrode 155 made of a conductive material such as a metal is formed on the gate insulating layer 153 such that the gate electrode 155 corresponds to a central portion of the semiconductor layer 152.

Although the gate insulating layer 153 is shown in FIG. 2 as being formed throughout the entire surface of the flexible substrate 140, the present disclosure is not limited thereto. The gate insulating layer 153 may be patterned to have the same shape as that of the gate electrode 155.

An interlayer insulating layer 157 made of an insulating material is formed on the gate electrode 155. The interlayer insulating layer 157 may be formed of an inorganic insulating material such as silicon oxide or silicon nitride or an organic insulating material such as benzocyclobutene or photoreactive acrylic. The interlayer insulating layer 157 has first and second contact holes 154 and 156 configured to expose opposite sides of the semiconductor layer 152. The first and second contact holes 154 and 156 are disposed at opposite sides of the gate electrode 155 and spaced apart from the gate electrode 155.

In this case, the first and second contact holes 154 and 156 are also formed in the gate insulating layer 153. When the gate insulating layer 153 is patterned to have the same shape as that of the gate electrode 155, differently from the above case, the first and second contact holes 154 and 156 may be formed only in the interlayer insulating layer 157.

A source electrode 160 and a drain electrode 162, which are made of a conductive material such as a metal, are formed on the interlayer insulating layer 157. The source electrode 160 and the drain electrode 162 are spaced apart from each other with reference to the gate electrode 155, and contact opposite sides of the semiconductor layer 152 through the first and second contact holes 154 and 156, respectively.

The semiconductor layer 152, the gate electrode 155, the source electrode 160, and the drain electrode 162 described above constitute the thin film transistor Tr. The thin film transistor Tr may be a driving transistor configured to control current flowing through the light emitting diode D.

Although the thin film transistor Tr is shown in FIG. 2 as having a coplanar structure in which the gate electrode 155, the source electrode 160, and the drain electrode 162 are disposed over the semiconductor layer 152, the present disclosure is not limited thereto. The thin film transistor Tr may have an inverted staggered structure in which a gate electrode is disposed under a semiconductor layer, and a source electrode and a drain electrode are disposed over the semiconductor layer. In this case, the semiconductor layer may be made of amorphous silicon.

Although not shown, a gate line and a data line define a pixel area through intersection thereof, and a switching element connected to the gate line and the data line is further formed. The switching element is connected to the driving transistor Tr.

In addition, a power line is formed to extend in parallel to the gate line or the data line in a state of being spaced apart from the gate line or the data line. A storage capacitor configured to constantly maintain a voltage of the gate electrode of the driving transistor Tr for one frame may be further configured.

A protective layer 164 having a drain contact hole 166 configured to expose the drain electrode 162 of the thin film transistor Tr is formed to cover the thin film transistor Tr.

A first electrode 170 connected to the drain electrode 162 of the thin film transistor Tr through the drain contact hole 166 is formed in the protective layer 164 such that the first electrode 170 is separated from first electrodes 170 of other pixel areas. The first electrode 170 may be an anode and may be made of a conductive material having a relatively great work function. For example, the first electrode 170 may be made of a transparent conductive material such as indium tin oxide (ITO) or indium zinc oxide (IZO).

Meanwhile, when the display panel 110 according to the embodiment of the present disclosure is a top-emission type organic light emitting diode panel, a reflective electrode or a reflective layer may be further formed under the first electrode 170. For example, the reflective electrode or the reflective layer may be made of an aluminum-palladium-copper (APC) alloy.

In addition, a bank layer 176 configured to cover an edge of the first electrode 170 is formed on the protective layer 164. The bank layer 176 exposes a central portion of the first electrode 170, correspondingly to the pixel area.

An organic emission layer 172 is formed on the first electrode 170. The organic emission layer 172 may be an emitting material layer made of an emitting material and having a single-layer structure. Differently from this case, the organic emission layer 172 may have a multilayer structure of a hole injection layer, a hole transport layer, an emitting material layer, an electron transport layer, and an electron injection layer sequentially stacked on the first electrode 170, to enhance luminous efficacy.

A second electrode 174 is formed over the flexible substrate 140 formed with the organic emission layer 172. The second electrode 174 is disposed on the entirety of the active area and is made of a conductive material having a relatively small work function, and, as such, may be used as a cathode. For example, the second electrode 174 may be made of aluminum (Al), magnesium (Mg), silver (Ag), or an alloy thereof.

The first electrode 170, the organic emission layer 172, and the second electrode 174 constitute the light emitting diode D.

The encapsulation film 180 is formed on the second electrode 174 to prevent or suppress ambient moisture from penetrating the light emitting diode D. The encapsulation film 180 may have a stacked structure of a first inorganic insulating layer 182, an organic insulating layer 184, and a second inorganic insulating layer 186, without being limited thereto.

In addition, a polarization plate (not shown) configured to reduce reflection of external light may be attached to the encapsulation film 180. For example, the polarization plate may be a circular polarization plate.

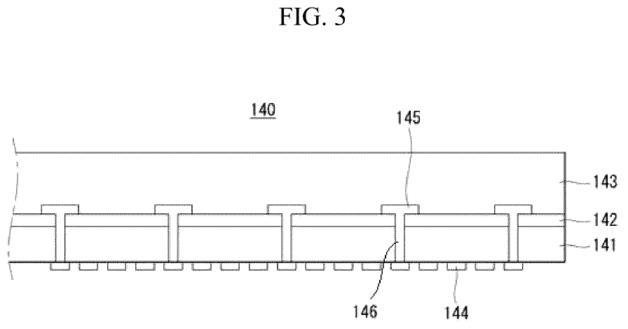

FIG. 3 is a cross-sectional view showing the flexible substrate 140 according to an example embodiment of the present disclosure.

As shown in FIG. 3, the flexible substrate 140 of the display panel 110 according to the embodiment of the present disclosure may include a lower layer 141, an intermediate layer 142, and an upper layer 143. The flexible substrate 140 may have a stacked structure in which the intermediate layer 142 is interposed between the lower layer 141 and the upper layer 143.

The lower layer 141 and the upper layer 143 may be constituted by a plastic material. For example, the lower layer 141 and the upper layer 143 may be made of a polymer material such as polyimide, polyethylene terephthalate, polyethylene naphthalate, polycarbonate, polyethersulfone, polyarylate, polysulfone, cyclic-olefin copolymer, or the like.

The intermediate layer 142 may be constituted by, for example, a single-layer structure or a stacked structure of an inorganic material such as silicon oxide (SiOₓ), silicon nitride (SiNₓ), or silicon oxynitride (SiOₓN_{y}).

A first transparent electrode layer 144 is disposed on a back surface of the lower layer 141. A second transparent electrode layer 145 is disposed between the intermediate layer 142 and the upper layer 143. A plurality of contact holes are formed in the lower layer 141 and the intermediate layer 142. The first transparent electrode layer 144 and the second transparent electrode layer 145 are electrically interconnected by a connection electrode 146 filling each contact hole. The connection electrode 146 may be formed of the same material as that of the first transparent electrode layer 144 or the second transparent electrode layer 145. It is preferred that the connection electrode 146 be formed of the same material as that of the second transparent electrode layer 145, for process convenience.

Each of the first transparent electrode layer 144 and the second transparent electrode layer 145 may be configured to have various patterns.

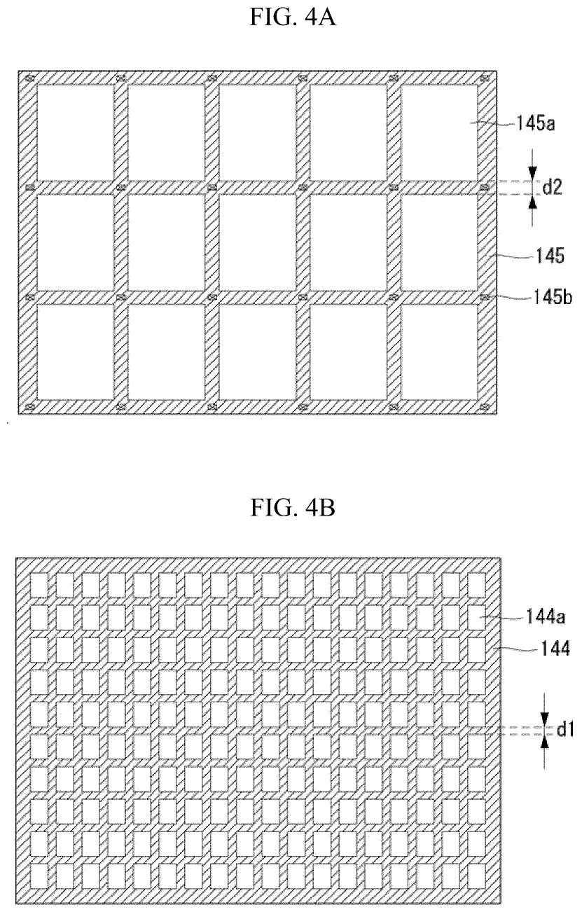

FIG. 4A is a plan view of a second transparent electrode layer according to a first example embodiment of the present disclosure. FIG. 4B is a plan view of a first transparent electrode layer according to the first example embodiment of the present disclosure.

As shown in FIG. 4A, the second transparent electrode layer according to the first example embodiment of the present disclosure, which is designated by reference numeral “145”, is disposed between the intermediate layer 142 and the upper layer 143 of the flexible substrate 140. The second transparent electrode layer 145 may include a plurality of second open portions 145a. The plurality of second open portions 145a have a uniform size and are disposed at a uniform density.

As shown in FIG. 4B, the first transparent electrode layer according to the first example embodiment of the present disclosure, which is designated by reference numeral “144”, is disposed on the back surface of the lower layer 141 of the flexible substrate 140. The first transparent electrode layer 144 includes a plurality of first open portions 144a. The plurality of first open portions 144a also have a uniform size and are disposed at a uniform density.

As shown in FIGS. 4A and 4B, the first transparent electrode layer 144 and the second transparent electrode layer 145 are electrically interconnected through a plurality of contact holes 145b. The plurality of contact holes 145b are also disposed at a uniform density. As described with reference to FIG. 3, the first transparent electrode layer 144 and the second transparent electrode layer 145 are electrically interconnected through the connection electrodes 146 respectively filling the plurality of contact holes 145b.

As shown in FIGS. 4A and 4B, the size of each first open portion 144a is smaller than the size of each second open portion 145a. In addition, the number of the first open portions 144a is greater than the number of the second open portions 145a, and the density of the first open portions 144a is higher than the density of the second open portions 145a.

In addition, a line width d1 of the first transparent electrode layer 144 between the first open portions 144a is narrower than a line width d2 of the second transparent electrode layer 145 between the second open portions 145a. Accordingly, the resistance value of the first transparent electrode layer 144 is greater than the resistance value of the second transparent electrode layer 145.

Accordingly, when a voltage (current) is applied to the second transparent electrode layer 145, the first transparent electrode layer 144 may generate heat.

Since the resistance values of the first and second transparent electrode layers 144 and 145 may vary in accordance with a voltage (current) application direction, the first and second transparent electrode layers 144 and 145 may be configured to have various patterns to compensate for resistance variation.

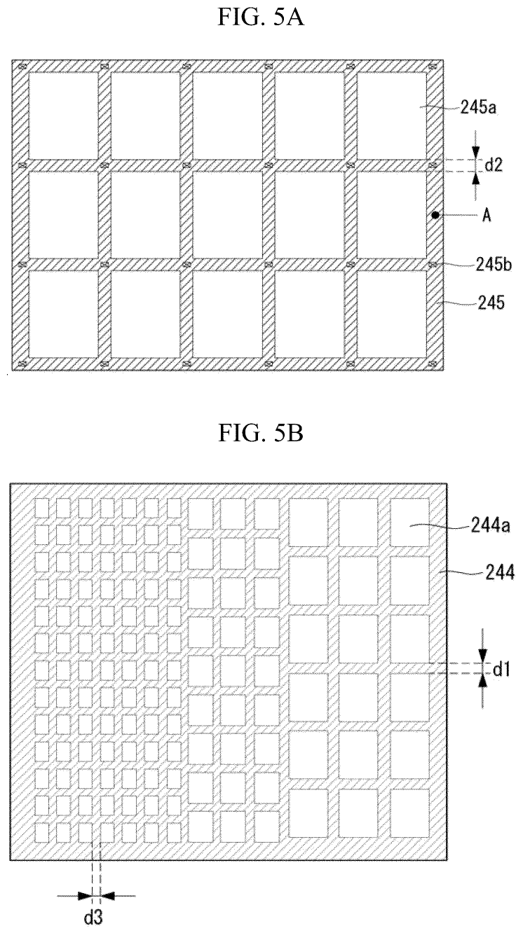

FIG. 5A is a plan view of a second transparent electrode layer according to a second example embodiment of the present disclosure. FIG. 5B is a plan view of a first transparent electrode layer according to the second example embodiment of the present disclosure. FIGS. 5A and 5B show an example embodiment in which a voltage (current) is applied to one side A of the second transparent electrode layer.

As shown in FIG. 5A, the second transparent electrode layer according to the second example embodiment of the present disclosure, which is designated by reference numeral “245”, is disposed between the intermediate layer 142 and the upper layer 143 of the flexible substrate 140. The second transparent electrode layer 245 may include a plurality of second open portions 245a. The plurality of second open portions 245a have a uniform size and are disposed at a uniform density.

As shown in FIG. 5B, the first transparent electrode layer according to the second example embodiment of the present disclosure, which is designated by reference numeral “244”, is disposed on the back surface of the lower layer 141 of the flexible substrate 140. The first transparent electrode layer 244 includes a plurality of first open portions 244a. The plurality of first open portions 244a may have different sizes in accordance with positions thereof and may be disposed at different densities in accordance with positions thereof.

As shown in FIGS. 5A and 5B, the first transparent electrode layer 244 and the second transparent electrode layer 245 are electrically interconnected through a plurality of contact holes 245b. The plurality of contact holes 245b are also disposed at a uniform density. As described with reference to FIG. 3, the first transparent electrode layer 244 and the second transparent electrode layer 245 are electrically interconnected through the connection electrodes 146 respectively filling the plurality of contact holes 245b.

The configuration of the second transparent electrode layer 245 according to the second embodiment of the present disclosure is identical to the configuration of the second transparent electrode layer 145 described with reference to FIG. 4A. Of course, it is assumed that a voltage (current) is applied to one side A of the second transparent electrode layer 245.

As shown in FIGS. 5A and 5B, the size of each first open portion 244a is smaller than the size of each second open portion 245a. In addition, the number of the first open portions 244a is greater than the number of the second open portions 245a, and the density of the first open portions 244a is higher than the density of the second open portions 245a.

In addition, a line width d1 of the first transparent electrode layer 244 between the first open portions 244a is narrower than a line width d2 of the second transparent electrode layer 245 between the second open portions 245a. Accordingly, the resistance value of the first transparent electrode layer 244 is greater than the resistance value of the second transparent electrode layer 245.

Accordingly, when a voltage (current) is applied to the second transparent electrode layer 245, the first transparent electrode layer 244 may generate heat.

In addition, the size of the plurality of first open portions 244a of the first transparent electrode layer 244 and the line width of the first transparent electrode layer 244 between the first open portions 244a may be varied in accordance with a voltage (current) application direction.

For example, when it is assumed that a voltage (current) is applied to one side A of the second transparent electrode layer 245, the size of the first open portions 244a of the first transparent electrode layer 244 is gradually decreased as the first transparent electrode layer 244 extends from a region thereof corresponding to the side A, to which the voltage (current) is applied, in a direction opposite to the voltage (current) application region, and the density of the first open portions 244a of the first transparent electrode layer 244 is gradually increased as the first transparent electrode layer 244 extends from the voltage (current) application region in the direction opposite to the voltage (current) application region. Accordingly, the line width of the first transparent electrode layer 244 between the first open portions 244a is gradually decreased as the first transparent electrode layer 244 extends from the voltage (current) application region in the direction opposite to the voltage (current) application region. For example, when it is assumed that the line width of the first transparent electrode layer 244 between the first open portions 244a in the voltage (current) application region is “d1”, and the line width of the first transparent electrode layer 244 between the first open portions 244a in a region remote from the voltage (current) application region is “d3”, d1 is greater than d3.

Accordingly, even when the resistance value of the second transparent electrode layer 245 is varied in the voltage (current) application direction, the first transparent electrode layer 244 may uniformly generate heat in the entire region thereof because the line width of the first transparent electrode layer 244 is varied in accordance with the voltage (current) application direction.

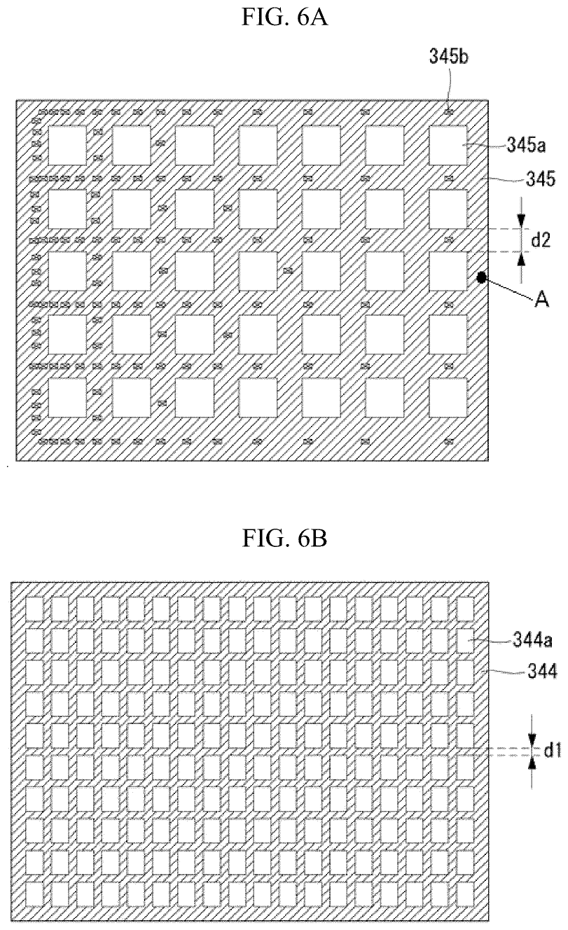

FIG. 6A is a plan view of a second transparent electrode layer according to a third example embodiment of the present disclosure. FIG. 6B is a plan view of a first transparent electrode layer according to the third example embodiment of the present disclosure. FIGS. 6A and 6B show an example embodiment in which a voltage (current) is applied to one side A of the second transparent electrode layer.

As shown in FIG. 6A, the second transparent electrode layer according to the third example embodiment of the present disclosure, which is designated by reference numeral “345”, is disposed between the intermediate layer 142 and the upper layer 143 of the flexible substrate 140. The second transparent electrode layer 345 may include a plurality of second open portions 345a. The plurality of second open portions 345a have a uniform size and are disposed at a uniform density.

As shown in FIG. 6B, the first transparent electrode layer according to the third example embodiment of the present disclosure, which is designated by reference numeral “344”, is disposed on the back surface of the lower layer 141 of the flexible substrate 140. The first transparent electrode layer 344 includes a plurality of first open portions 344a. The plurality of first open portions 344a have a uniform size and are disposed at a uniform density.

As shown in FIGS. 6A and 6B, the first transparent electrode layer 344 and the second transparent electrode layer 345 are electrically interconnected through a plurality of contact holes 345b. The plurality of contact holes 345b are disposed at different densities in accordance with a voltage (current) application direction. As described with reference to FIG. 3, the first transparent electrode layer 344 and the second transparent electrode layer 345 are electrically interconnected through the connection electrodes 146 respectively filling the plurality of contact holes 345b.

The configuration of the second transparent electrode layer 345 according to the third example embodiment of the present disclosure is identical to the configuration of the second transparent electrode layer 145 described with reference to FIG. 4A. Of course, it is assumed that a voltage (current) is applied to one side A of the second transparent electrode layer 345.

As shown in FIGS. 6A and 6B, the size of each first open portion 344a is smaller than the size of each second open portion 345a. In addition, the number of the first open portions 344a is greater than the number of the second open portions 345a, and the density of the first open portions 344a is higher than the density of the second open portions 345a.

In addition, a line width d1 of the first transparent electrode layer 344 between the first open portions 344a is narrower than a line width d2 of the second transparent electrode layer 345 between the second open portions 345a. Accordingly, the resistance value of the first transparent electrode layer 344 is greater than the resistance value of the second transparent electrode layer 345.

Accordingly, when a voltage (current) is applied to the second transparent electrode layer 345, the first transparent electrode layer 344 may generate heat.

In addition, the density of the plurality of contact holes 345b may be varied in accordance with the voltage (current) application direction.

For example, when it is assumed that a voltage (current) is applied to one side A of the second transparent electrode layer 345, the density of the plurality of contact holes 345b may be gradually increased as the second transparent electrode layer 345 extends from one side A of the second transparent electrode layer 345, to which the voltage (current) is applied, in a direction opposite to the side A of the second transparent electrode layer 345.

Accordingly, even when the resistance value of the second transparent electrode layer 345 is varied in the voltage (current) application direction, the first transparent electrode layer 344 may uniformly generate heat in the entire region thereof because the density of the plurality of contact holes 345b is varied in accordance with the voltage (current) application direction.

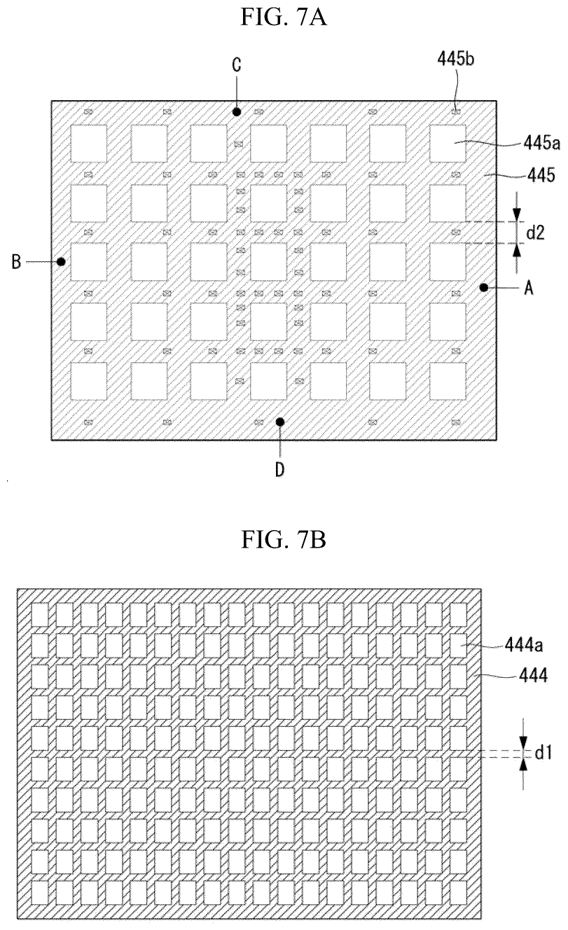

FIG. 7A is a plan view of a second transparent electrode layer according to a fourth example embodiment of the present disclosure. FIG. 7B is a plan view of a first transparent electrode layer according to the fourth example embodiment of the present disclosure. FIGS. 7A and 7B show an example embodiment in which a voltage (current) is applied to left, right, upper, and lower sides A, B, C, and D of the second transparent electrode layer.

As shown in FIG. 7A, the second transparent electrode layer according to the fourth example embodiment of the present disclosure, which is designated by reference numeral “445”, is disposed between the intermediate layer 142 and the upper layer 143 of the flexible substrate 140. The second transparent electrode layer 445 may include a plurality of second open portions 445a and a plurality of second contact holes 445b. The plurality of second open portions 445a have a uniform size and are disposed at a uniform density.

As shown in FIG. 7B, the first transparent electrode layer according to the fourth example embodiment of the present disclosure, which is designated by reference numeral “444”, is disposed on the back surface of the lower layer 141 of the flexible substrate 140. The first transparent electrode layer 444 includes a plurality of first open portions 444a. The plurality of first open portions 444a have a uniform size and are disposed at a uniform density.

As shown in FIGS. 7A and 7B, the first transparent electrode layer 444 and the second transparent electrode layer 445 are electrically interconnected through the plurality of contact holes 445b. The plurality of contact holes 445b are disposed at different densities in accordance with a voltage (current) application direction. For example, the density of the plurality of contact holes 445b may be gradually increased as the second transparent electrode layer 445 extends from the left, right, upper, and lower sides A, B, C, and D thereof, to which the voltage (current) is applied, toward a center thereof. As described with reference to FIG. 3, the first transparent electrode layer 444 and the second transparent electrode layer 445 are electrically interconnected through the connection electrodes 146 respectively filling the plurality of contact holes 445b.

As shown in FIGS. 7A and 7B, the size of each first open portion 444a is smaller than the size of each second open portion 445a. In addition, the number of the first open portions 444a is greater than the number of the second open portions 445a, and the density of the first open portions 444a is higher than the density of the second open portions 445a.

In addition, a line width d1 of the first transparent electrode layer 444 between the first open portions 444a is narrower than a line width d2 of the second transparent electrode layer 445 between the second open portions 445a. Accordingly, the resistance value of the first transparent electrode layer 444 is greater than the resistance value of the second transparent electrode layer 445.

Accordingly, when a voltage (current) is applied to the second transparent electrode layer 445, the first transparent electrode layer 444 may generate heat.

Since the voltage (current) is applied to the left, right, upper, and lower sides A, B, C, and D of the second transparent electrode layer 445, a gradual reduction in voltage (current) occurs due to surface resistance of the second transparent electrode layer 445 as the second transparent electrode layer 445 extends toward the center thereof. However, the first transparent electrode layer 444 may uniformly generate heat in the entire region thereof because the density of the plurality of contact holes 445b is gradually increased as the second transparent electrode layer 445 extends from the left, right, upper, and lower sides A, B, C, and D thereof toward the center thereof.

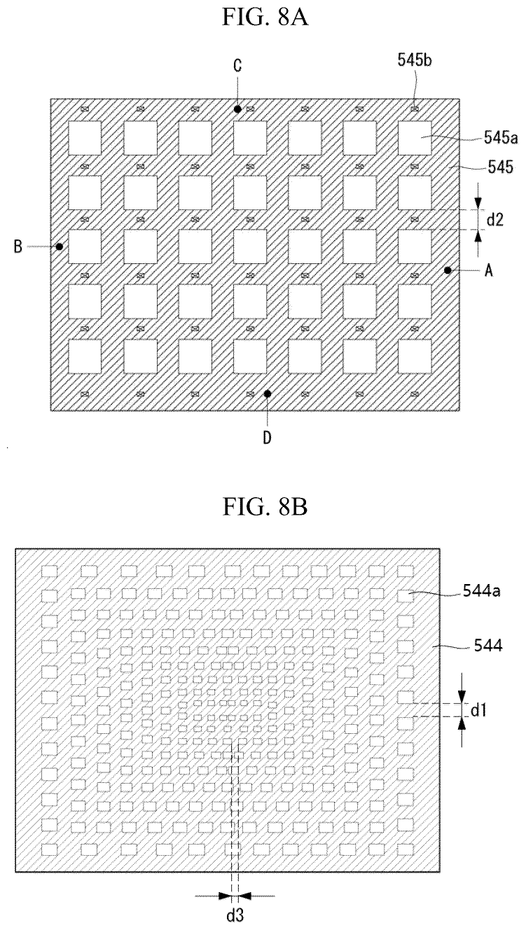

FIG. 8A is a plan view of a second transparent electrode layer according to a fifth example embodiment of the present disclosure. FIG. 8B is a plan view of a first transparent electrode layer according to the fifth example embodiment of the present disclosure. FIGS. 8A and 8B show an example embodiment in which a voltage (current) is applied to left, right, upper, and lower sides A, B, C, and D of the second transparent electrode layer.

As shown in FIG. 8A, the second transparent electrode layer according to the fifth example embodiment of the present disclosure, which is designated by reference numeral “545”, is disposed between the intermediate layer 142 and the upper layer 143 of the flexible substrate 140. The second transparent electrode layer 545 includes a plurality of second open portions 545a. The plurality of second open portions 545a have a uniform size and are disposed at a uniform density.

As shown in FIG. 8B, the first transparent electrode layer according to the fifth example embodiment of the present disclosure, which is designated by reference numeral “544”, is disposed on the back surface of the lower layer 141 of the flexible substrate 140. The first transparent electrode layer 544 includes a plurality of first open portions 544a. The plurality of first open portions 544a may have different sizes in accordance with positions thereof and may be disposed at different densities in accordance with positions thereof.

As shown in FIGS. 8A and 8B, the first transparent electrode layer 544 and the second transparent electrode layer 545 are electrically interconnected through a plurality of contact holes 545b. The plurality of contact holes 545b are also disposed at a uniform density. As described with reference to FIG. 3, the first transparent electrode layer 544 and the second transparent electrode layer 545 may be electrically interconnected through the connection electrodes 146 respectively filling the plurality of contact holes 545b.

As shown in FIGS. 8A and 8B, the size of each first open portion 544a is smaller than the size of each second open portion 545a. In addition, the number of the first open portions 544a is greater than the number of the second open portions 545a, and the density of the first open portions 544a is higher than the density of the second open portions 545a.

In addition, a line width d1 of the first transparent electrode layer 544 between the first open portions 544a is narrower than a line width d2 of the second transparent electrode layer 545 between the second open portions 545a. Accordingly, the resistance value of the first transparent electrode layer 544 is greater than the resistance value of the second transparent electrode layer 545.

Accordingly, when a voltage (current) is applied to the second transparent electrode layer 545, the first transparent electrode layer 544 may generate heat.

In addition, the size of the plurality of first open portions 544a of the first transparent electrode layer 544 and the line width of the first transparent electrode layer 544 between the first open portions 544a may be varied in accordance with a voltage (current) application direction.

For example, when it is assumed that a voltage (current) is applied to left, right, upper, and lower sides A, B, C, and D of the second transparent electrode layer 545, the size of the first open portions 544a of the first transparent electrode layer 544 is gradually decreased as the first transparent electrode layer 544 extends from regions thereof corresponding to the left, right, upper, and lower sides A, B, C, and D, to which the voltage (current) is applied, toward a central region thereof, and the density of the first open portions 544a of the first transparent electrode layer 544 is gradually increased as the first transparent electrode layer 544 extends from the regions thereof corresponding to the left, right, upper, and lower sides A, B, C, and D, to which the voltage (current) is applied, toward the central region thereof. Accordingly, the line width of the first transparent electrode layer 544 between the first open portions 544a is gradually decreased as the first transparent electrode layer 544 extends from the regions thereof corresponding to the left, right, upper, and lower sides A, B, C, and D, to which the voltage (current) is applied, toward the central region thereof. For example, when it is assumed that the line width of the first transparent electrode layer 544 between the first open portions 544a in the regions corresponding to the left, right, upper, and lower sides A, B, C, and D, to which the voltage (current) is applied, is “d1”, and the line width of the first transparent electrode layer 544 between the first open portions 544a in the central region is “d3”, d1 is greater than d3.

Accordingly, even when the resistance value of the second transparent electrode layer 545 is varied in the voltage (current) application direction, the first transparent electrode layer 544 may uniformly generate heat because the line width of the first transparent electrode layer 544 is varied in accordance with the voltage (current) application direction.

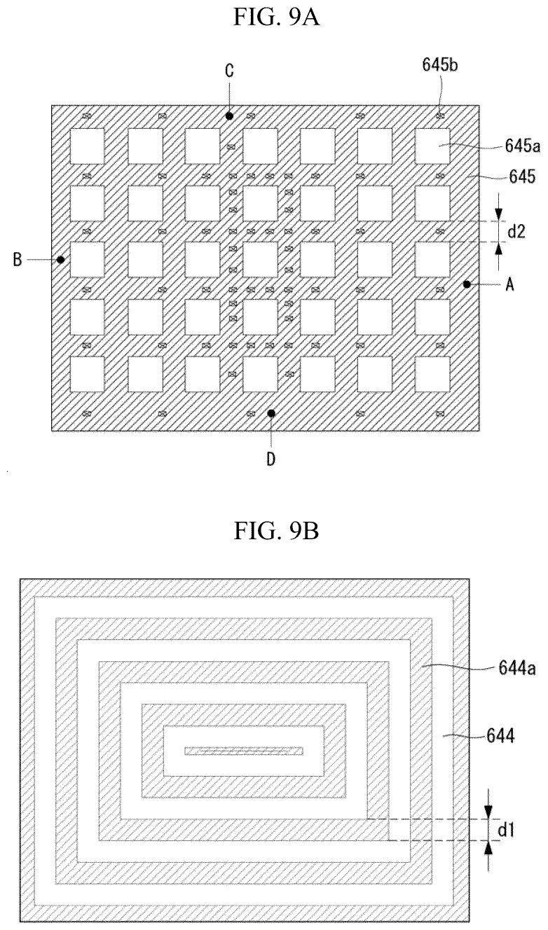

FIG. 9A is a plan view of a second transparent electrode layer according to a sixth example embodiment of the present disclosure. FIG. 9B is a plan view of a first transparent electrode layer according to the sixth example embodiment of the present disclosure. FIGS. 9A and 9B show an example embodiment in which a voltage (current) is applied to left, right, upper, and lower sides A, B, C, and D of the second transparent electrode layer.

As shown in FIG. 9A, the second transparent electrode layer according to the sixth example embodiment of the present disclosure, which is designated by reference numeral “645”, is disposed between the intermediate layer 142 and the upper layer 143 of the flexible substrate 140. The second transparent electrode layer 645 includes a plurality of second open portions 645a. The plurality of second open portions 645a may have a uniform size and may be disposed at a uniform density.

As shown in FIG. 9B, the first transparent electrode layer according to the sixth example embodiment of the present disclosure, which is designated by reference numeral “644”, is disposed on the back surface of the lower layer 141 of the flexible substrate 140. The first transparent electrode layer 644 includes a plurality of first open portions 644a. Each of the plurality of first open portions 644a has a quadrangular ring shape. The plurality of first open portions 644a have different sizes, respectively, and smaller ones thereof are sequentially disposed inside an outermost one thereof having a largest size in such a manner that smaller ones thereof are disposed inside larger ones thereof.

As shown in FIGS. 9A and 9B, the first transparent electrode layer 644 and the second transparent electrode layer 645 are electrically interconnected through a plurality of contact holes 645b. The plurality of contact holes 645b are disposed at different densities in accordance with the voltage (current) application direction. For example, the density of the plurality of contact holes 645b may be gradually increased as the second transparent electrode layer 645 extends from the left, right, upper, and lower sides A, B, C, and D thereof, to which the voltage (current) is applied, toward a center thereof. As described with reference to FIG. 3, the first transparent electrode layer 644 and the second transparent electrode layer 645 are electrically interconnected through the connection electrodes 146 respectively filling the plurality of contact holes 645b.

In addition, as shown in FIGS. 9A and 9B, a line width d1 of the first transparent electrode layer 644 between the first open portions 644a are narrower than a line width d2 of the second transparent electrode layer 645 between the second open portions 645a. Accordingly, the resistance value of the first transparent electrode layer 644 is greater than the resistance value of the second transparent electrode layer 645.

Accordingly, when a voltage (current) is applied to the second transparent electrode layer 645, the first transparent electrode layer 644 may generate heat.

Since the voltage (current) is applied to the left, right, upper, and lower sides A, B, C, and D of the second transparent electrode layer 645, a gradual reduction in voltage (current) occurs due to surface resistance of the second transparent electrode layer 645 as the second transparent electrode layer 645 extends toward the center thereof. However, the first transparent electrode layer 644 may uniformly generate heat in the entire region thereof because the density of the plurality of contact holes 645b is gradually increased as the second transparent electrode layer 645 extends from the left, right, upper, and lower sides A, B, C, and D thereof toward the center thereof.

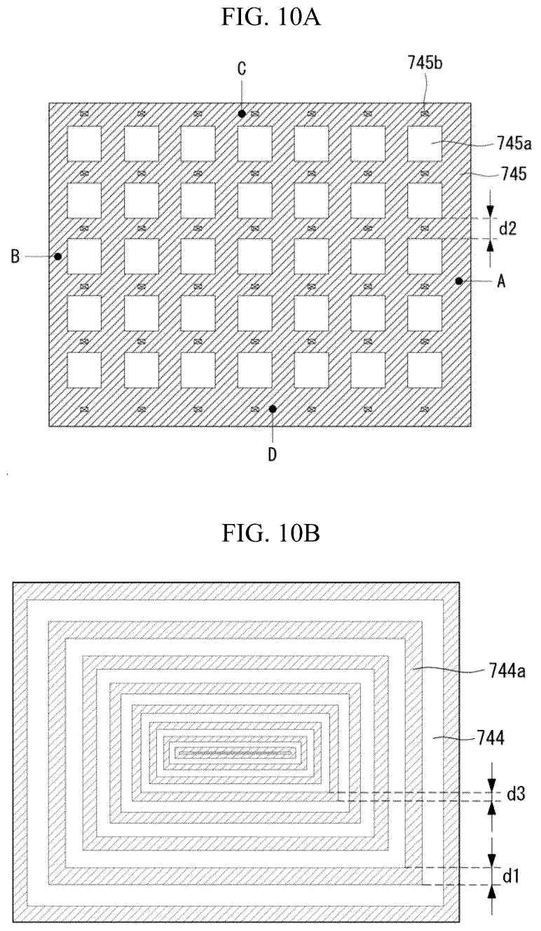

FIG. 10A is a plan view of a second transparent electrode layer according to a seventh example embodiment of the present disclosure. FIG. 10B is a plan view of a first transparent electrode layer according to the seventh example embodiment of the present disclosure. FIGS. 10A and 10B show an example embodiment in which a voltage (current) is applied to left, right, upper, and lower sides A, B, C, and D of the second transparent electrode layer.

As shown in FIG. 10A, the second transparent electrode layer according to the seventh example embodiment of the present disclosure, which is designated by reference numeral “745”, is disposed between the intermediate layer 142 and the upper layer 143 of the flexible substrate 140. The second transparent electrode layer 745 includes a plurality of second open portions 745a. The plurality of second open portions 745a has a uniform size and is disposed at a uniform density.

As shown in FIG. 10B, the first transparent electrode layer according to the seventh example embodiment of the present disclosure, which is designated by reference numeral “744”, is disposed on the back surface of the lower layer 141 of the flexible substrate 140. The first transparent electrode layer 744 includes a plurality of first open portions 744a. Each of the plurality of first open portions 744a has a quadrangular ring shape. The plurality of first open portions 744a have different sizes, respectively, and smaller ones thereof are sequentially disposed inside an outermost one thereof having a largest size in such a manner that smaller ones thereof are disposed inside larger ones thereof.

As shown in FIGS. 10A and 10B, the first transparent electrode layer 744 and the second transparent electrode layer 745 are electrically interconnected through a plurality of contact holes 745b. The plurality of contact holes 745b are disposed at a uniform density. As described with reference to FIG. 3, the first transparent electrode layer 744 and the second transparent electrode layer 745 may be electrically interconnected through the connection electrodes 146 respectively filling the plurality of contact holes 745b.

As shown in FIGS. 10A and 10B, a line width d1 of the first transparent electrode layer 744 between the first open portions 744a is narrower than a line width d2 of the second transparent electrode layer 745 between the second open portions 745a. Accordingly, the resistance value of the first transparent electrode layer 744 is greater than the resistance value of the second transparent electrode layer 745.

Accordingly, when a voltage (current) is applied to the second transparent electrode layer 745, the first transparent electrode layer 744 may generate heat.

In addition, the size of the plurality of first open portions 744a of the first transparent electrode layer 744 and the line width of the first transparent electrode layer 744 between the first open portions 744a may be varied in accordance with a voltage (current) application direction.

For example, when it is assumed that a voltage (current) is applied to left, right, upper, and lower sides A, B, C, and D of the second transparent electrode layer 745, widths of the plurality of first open portions 744a of the first transparent electrode layer 744 are equal, and the line width of the first transparent electrode layer 744 between the first open portions 744a may be gradually decreased as the first transparent electrode layer 744 extends from regions thereof corresponding to the left, right, upper, and lower sides A, B, C, and D, to which the voltage (current) is applied, toward a central region thereof. For example, when it is assumed that the line width of the first transparent electrode layer 744 between the first open portions 744a in the regions corresponding to the left, right, upper, and lower sides A, B, C, and D, to which the voltage (current) is applied, is “d1”, and the line width of the first transparent electrode layer 744 between the first open portions 744a in the central region is “d3”, d1 is greater than d3.

Accordingly, even when the resistance value of the second transparent electrode layer 745 is varied in the voltage (current) application direction, the first transparent electrode layer 744 may uniformly generate heat because the line width of the first transparent electrode layer 744 is varied in accordance with the voltage (current) application direction.

In the seventh embodiment of the present disclosure shown in FIGS. 10A and 10B, the widths of the plurality of first open portions 744a of the first transparent electrode layer 744 may also be gradually decreased as the first transparent electrode layer 744 extends from the regions thereof corresponding to the left, right, upper, and lower sides A, B, C, and D, to which the voltage (current) is applied, toward the central region thereof.

Hereinafter, a method of manufacturing a display apparatus in accordance with an example embodiment of the present disclosure will be described.

A flexible display apparatus employs a flexible substrate, and the flexible substrate has flexible characteristics. For this reason, it is difficult to form the multi-buffer layer 151, the thin film transistor Tr, the light emitting diode D, and the encapsulation film 180 described with reference to FIG. 2 on the flexible substrate.

For this reason, a process is performed under the condition that the plastic substrate is attached to one surface of a carrier substrate such as a glass substrate. After completion of the process, the carrier substrate is separated from the plastic substrate and, as such, a display apparatus is manufactured.

When separation of the carrier substrate from the plastic substrate is carried out through laser irradiation, the surface of the plastic substrate may be damaged. Furthermore, an impact may be generated during substrate separation and, as such, damage to one or more elements of the display apparatus may occur.

In example embodiments of the present disclosure, a transparent electrode layer is disposed on the flexible substrate, and a voltage (current) is applied to the transparent electrode layer such that the transparent electrode layer generates heat. Through heat generated from the transparent electrode layer (Joule heating), it is possible to easily separate the carrier substrate from the flexible substrate.

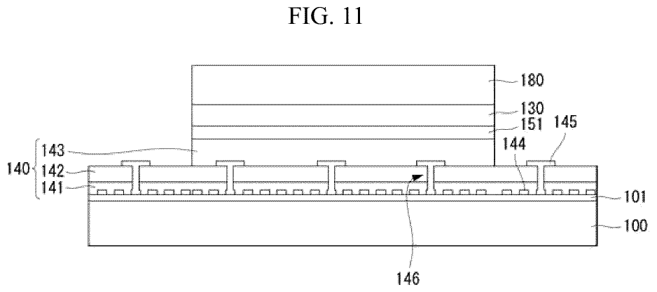

FIG. 11 is a cross-sectional view explaining a method of manufacturing a display apparatus in accordance with an example embodiment of the present disclosure.

A separation layer 101 is formed on a carrier substrate 100. The separation layer 101 is formed to have a small thickness because the separation layer 101 functions as a sacrificial layer. For example, the separation layer 101 is formed to have a thickness of about 1 μm.

A transparent conductive material such as indium tin oxide (ITO) or indium zinc oxide (IZO) is deposited on the separation layer 101, and is then patterned to form a first transparent electrode layer 144. The first transparent electrode layer 144 has a plurality of open portions 144a, 244a, 344a, 444a, 544a, 644a, or 744a having various patterns, as described with reference to FIGS. 4B, 5B, 6B, 7B, 8B, 9B, or 10B.

A lower layer 141 and an intermediate layer 142 of a flexible substrate 140 as described with reference to FIG. 3 are sequentially formed on the first transparent electrode layer 144.

The lower layer 141 and the intermediate layer 142 are selectively removed, thereby forming a plurality of contact holes 146. A transparent conductive material such as indium tin oxide (ITO) or indium zinc oxide (IZO) is deposited on the intermediate layer 142, and is then patterned to form a second transparent electrode layer 145 such that the second transparent electrode layer 145 is electrically connected to the first transparent electrode layer 144 through the plurality of contact holes 146. The second transparent electrode layer 145 has a plurality of open portions 145a, 245a, 345a, 445a, 545a, 645a, or 745a having various patterns, as described with reference to FIGS. 4A, 5A, 6A, 7A, 8A, 9A, or 10A. The plurality of contact holes 146 is also formed to have various densities, as described with reference to FIGS. 4A, 5A, 6A, 7A, 8A, 9A, and 10A.

An upper layer 143 of the flexible substrate 140 is formed on the second transparent electrode layer 145.

Materials of the lower layer 141, the intermediate layer 142, and the upper layer 143 of the flexible substrate 140 are identical to those described with reference to FIG. 3.

A multi-buffer layer 151 is formed on the upper layer 143 of the flexible substrate 140.

A pixel layer, which is provided with a thin film transistor Tr and a light emitting diode D, and an encapsulation film 180 are sequentially formed on the multi-buffer layer 151, as described with reference to FIG. 2.

As described with reference to FIGS. 4A to 10B, voltage (current) is applied to the second transparent electrode layer 145 such that the first transparent electrode layer 144 generates heat to melt the separation layer 101. Thereafter, the carrier substrate 100 is separated from the flexible substrate 140.

Since the carrier substrate 100 is separated from the flexible substrate 140 under the condition that the first transparent electrode layer 144 generates heat, as described above, the flexible substrate 140 is free from foreign matter of the carrier substrate 100 or scratches of the carrier substrate 100.

Accordingly, it may be possible to prevent or suppress damage to the surface of the flexible substrate 140 and to prevent or suppress damage to one or more elements of the display apparatus caused by an impact generated during separation of the carrier substrate 100 from the flexible substrate 140.

In addition, the first and second transparent electrode layers may be used as a heat dissipation plate of the display apparatus.

In accordance with the present disclosure described above, it may be possible to reduce product costs because failure of the display apparatus is reduced.

In accordance with the present disclosure, environmental/social/governance (ESG) goals enabling a reduction in product costs may be achieved.

Flexible substrates and display apparatuses according to various example embodiments of the present disclosure may be explained as follows.

A flexible substrate according to an example embodiment of the present disclosure may include a first substrate layer made of a conductive material and having a plurality of first open portions, a second substrate layer disposed on the first substrate layer and having a plurality of contact holes, a third substrate layer disposed on the second substrate layer and electrically connected to the first substrate layer through the plurality of contact holes, the third substrate layer being made of a conductive material and having a plurality of second open portions, and a fourth substrate layer disposed on the third substrate layer.

In accordance with an example embodiment of the present disclosure, the second substrate layer may include a plastic material and an inorganic insulating layer, the fourth substrate layer may include a plastic material, and each of the first substrate layer and the third substrate layer may include a transparent electrode layer.

In accordance with an example embodiment of the present disclosure, the resistance of the first substrate layer may be smaller than the resistance of the third substrate layer.

In accordance with an example embodiment of the present disclosure, the line width of the first substrate layer between the plurality of first open portions may be narrower than the line width of the third substrate layer between the plurality of second open portions.

In accordance with an example embodiment of the present disclosure, the plurality of first open portions of the first substrate layer may have a uniform size and may be disposed at a uniform density. The plurality of contact holes may be disposed at a uniform density. The plurality of second open portions of the third substrate layer may have a uniform size and may be disposed at a uniform density. The size of the first open portions may be smaller than the size of the second open portions. The number of the plurality of first open portions may be greater than the number of the plurality of second open portions. The density of the plurality of first open portions may be higher than the density of the plurality of second open portions.

In accordance with an example embodiment of the present disclosure, the plurality of contact holes may be disposed at a uniform density and, the plurality of second open portions of the third substrate layer may have a uniform size and may be disposed at a uniform density. The size of the first open portions may be smaller than the size of the second open portions. The number of the plurality of first open portions may be greater than the number of the plurality of second open portions. The density of the plurality of first open portions may be higher than the density of the plurality of second open portions. The size of the plurality of first open portions and the line width of the first substrate layer between the plurality of first open portions may be varied in accordance with a voltage or current application direction.

In accordance with an example embodiment of the present disclosure, a voltage or current may be applied to one side of the third substrate layer, and the size of the plurality of first open portions may be gradually decreased as the first substrate layer extends from a region thereof corresponding to the side, to which the voltage or current is applied, in a direction opposite to the voltage or current application region. The density of the plurality of first open portions may be gradually increased as the first substrate layer extends from the voltage or current application region in the direction opposite to the voltage or current application region. The line width of the first substrate layer between the plurality of first open portions may be gradually decreased as the first substrate layer extends from the voltage or current application region in the direction opposite to the voltage or current application region.

In accordance with an example embodiment of the present disclosure, the plurality of first open portions of the first substrate layer may have a uniform size and may be disposed at a uniform density, and the plurality of second open portions of the third substrate layer may have a uniform size and may be disposed at a uniform density. The size of the first open portions may be smaller than the size of the second open portions. The number of the plurality of first open portions may be greater than the number of the plurality of second open portions. The density of the plurality of first open portions may be higher than the density of the plurality of second open portions. The density of the plurality of contact holes may be varied in accordance with a voltage or current application direction.

In accordance with an example embodiment of the present disclosure, a voltage or current may be applied to one side of the third substrate layer, and the density of the plurality of contact holes may be gradually increased as the second substrate layer extends from a region thereof corresponding to the side, to which the voltage or current is applied, in a direction opposite to the voltage or current application region.

In accordance with an example embodiment of the present disclosure, a voltage or current may be applied to upper, lower, left, and right sides of the third substrate layer, the plurality of first open portions of the first substrate layer may have a uniform size and may be disposed at a uniform density, and the plurality of second open portions of the third substrate layer may have a uniform size and may be disposed at a uniform density. The size of the first open portions may be smaller than the size of the second open portions. The number of the plurality of first open portions may be greater than the number of the plurality of second open portions. The density of the plurality of first open portions may be higher than the density of the plurality of second open portions. The density of the plurality of contact holes may be varied in accordance with a voltage or current application direction.

In accordance with an example embodiment of the present disclosure, the density of the plurality of contact holes may be gradually increased as the second substrate layer extends from regions thereof corresponding to the upper, lower, left, and right sides, to which the voltage or current is applied, toward a central region thereof.

In accordance with an example embodiment of the present disclosure, a voltage or current may be applied to upper, lower, left, and right sides of the third substrate layer, the plurality of contact holes may be disposed at a uniform density, and the plurality of second open portions of the third substrate layer may have a uniform size and may be disposed at a uniform density. The size of the first open portions may be smaller than the size of the second open portions. The number of the plurality of first open portions may be greater than the number of the plurality of second open portions. The density of the plurality of first open portions may be higher than the density of the plurality of second open portions. The size of the plurality of first open portions and the line width of the first substrate layer between the plurality of first open portions may be varied in accordance with a voltage or current application direction.

In accordance with an example embodiment of the present disclosure, the size of the plurality of first open portions may be gradually decreased as the first substrate layer extends from regions thereof corresponding to the upper, lower, left, and right sides, to which the voltage or current is applied, toward a central region thereof. The density of the plurality of first open portions may be gradually increased as the first substrate layer extends from the regions thereof corresponding to the upper, lower, left, and right sides, to which the voltage or current is applied, toward the central region thereof. The line width of the first substrate layer between the plurality of first open portions may be gradually decreased as the first substrate layer extends from the regions thereof corresponding to the upper, lower, left, and right sides, to which the voltage or current is applied, toward the central region thereof.

In accordance with an example embodiment of the present disclosure, each of the plurality of first open portions of the first substrate layer may have a quadrangular ring shape, and the plurality of first open portions may have different sizes, respectively, and smaller ones thereof may be sequentially disposed inside an outermost one thereof having a largest size in such a manner that smaller ones thereof are disposed inside larger ones thereof. The line width of the first substrate layer between the plurality of first open portions may be uniform. The plurality of second open portions of the third substrate layer may have a uniform size and may be disposed at a uniform density. The density of the plurality of contact holes may be varied in accordance with a voltage or current application direction.

In accordance with an example embodiment of the present disclosure, a voltage or current may be applied to upper, lower, left, and right sides of the third substrate layer, and the density of the plurality of contact holes may be gradually increased as the second substrate layer extends from regions thereof corresponding to the upper, lower, left, and right sides, to which the voltage or current is applied, toward a central region thereof.

In accordance with an example embodiment of the present disclosure, each of the plurality of first open portions of the first substrate layer may have a quadrangular ring shape, and the plurality of first open portions may have different sizes, respectively, and smaller ones thereof may be sequentially disposed inside an outermost one thereof having a largest size in such a manner that smaller ones thereof are disposed inside larger ones thereof. The plurality of contact holes may be disposed at a uniform density. The plurality of second open portions of the third substrate layer may have a uniform size and may be disposed at a uniform density. The size of the plurality of first open portions and the line width of the first substrate layer between the plurality of first open portions may be varied in accordance with a voltage or current application direction.

In accordance with an example embodiment of the present disclosure, a voltage or current may be applied to upper, lower, left, and right sides of the third substrate layer, and the size of the plurality of first open portions may be gradually decreased as the first substrate layer extends from regions thereof corresponding to the upper, lower, left, and right sides, to which the voltage or current is applied, toward a central region thereof. The line width of the first substrate layer between the plurality of first open portions may be gradually decreased as the first substrate layer extends from the regions thereof corresponding to the upper, lower, left, and right sides, to which the voltage or current is applied, toward the central region thereof.

A display apparatus according to an example embodiment of the present disclosure may include a flexible substrate according to an embodiment of the present disclosure, a thin film transistor on the flexible substrate, an organic light emitting diode connected to the thin film transistor, and an encapsulation film disposed on the organic light emitting diode.

A method of manufacturing a display apparatus in accordance with an example embodiment of the present disclosure may include forming a separation layer on a carrier substrate, forming, on the separation layer, a first substrate layer made of a conductive material and having a plurality of first open portions, forming, on the first substrate layer, a second substrate layer having a plurality of contact holes, forming, on the second substrate layer, a third substrate layer electrically connected to the first substrate layer through the plurality of contact holes and made of a conductive material, the third substrate layer having a plurality of second open portions. forming a fourth substrate layer on the third substrate layer, sequentially forming, on the fourth substrate layer, a pixel layer with a thin film transistor and a light emitting diode and an encapsulation film, and separating the carrier substrate by applying a voltage or current to the third substrate layer such that the first substrate layer generates heat.

The present disclosure described above is not limited to the above-described example embodiments and the accompanying drawings. Accordingly, it will be understood by those skilled in the art that various substitutions, changes, and modifications may be made without departing from the scope of the disclosure.

What is claimed is:

1. A flexible substrate, comprising:
a first substrate layer made of a conductive material and having a plurality of first open portions;
a second substrate layer disposed on the first substrate layer and having a plurality of contact holes;
a third substrate layer disposed on the second substrate layer and electrically connected to the first substrate layer through the plurality of contact holes, the third substrate layer being made of a conductive material and having a plurality of second open portions; and
a fourth substrate layer disposed on the third substrate layer.

2. The flexible substrate according to claim 1, wherein:
the second substrate layer comprises a plastic material and an inorganic insulating layer;
the fourth substrate layer comprises a plastic material; and
each of the first substrate layer and the third substrate layer comprises a transparent electrode layer.

3. The flexible substrate according to claim 1, wherein a resistance of the third substrate layer is smaller than a resistance of the first substrate layer.

4. The flexible substrate according to claim 1, wherein a line width of the first substrate layer between the plurality of first open portions is narrower than a line width of the third substrate layer between the plurality of second open portions.

5. The flexible substrate according to claim 4, wherein:
the plurality of first open portions of the first substrate layer have a uniform size and are disposed at a uniform density;
the plurality of contact holes are disposed at a uniform density;
the plurality of second open portions of the third substrate layer have a uniform size and are disposed at a uniform density;
the size of the first open portions is smaller than the size of the second open portions;
a number of the plurality of first open portions is greater than a number of the plurality of second open portions; and
the density of the plurality of first open portions is higher than the density of the plurality of second open portions.

6. The flexible substrate according to claim 4, wherein:
the plurality of contact holes are disposed at a uniform density;
the plurality of second open portions of the third substrate layer have a uniform size and are disposed at a uniform density;
a size of the first open portions is smaller than the size of the second open portions;
a number of the plurality of first open portions is greater than a number of the plurality of second open portions;
a density of the plurality of first open portions is higher than the density of the plurality of second open portions; and
the size of the plurality of first open portions and the line width of the first substrate layer between the plurality of first open portions are varied in accordance with a voltage or current application direction.

7. The flexible substrate according to claim 6, wherein:
a voltage or current is applied to one side of the third substrate layer;
the size of the plurality of first open portions is gradually decreased as the first substrate layer extends from a region thereof corresponding to the side, to which the voltage or current is applied, in a direction opposite to the voltage or current application region;
the density of the plurality of first open portions is gradually increased as the first substrate layer extends from the voltage or current application region in the direction opposite to the voltage or current application region; and
the line width of the first substrate layer between the plurality of first open portions is gradually decreased as the first substrate layer extends from the voltage or current application region in the direction opposite to the voltage or current application region.

8. The flexible substrate according to claim 4, wherein:
the plurality of first open portions of the first substrate layer have a uniform size and are disposed at a uniform density;
the plurality of second open portions of the third substrate layer have a uniform size and are disposed at a uniform density;
the size of the first open portions is smaller than the size of the second open portions;
a number of the plurality of first open portions is greater than a number of the plurality of second open portions;
the density of the plurality of first open portions is higher than the density of the plurality of second open portions; and
a density of the plurality of contact holes is varied in accordance with a voltage or current application direction.

9. The flexible substrate according to claim 8, wherein:
a voltage or current is applied to one side of the third substrate layer; and
the density of the plurality of contact holes is gradually increased as the second substrate layer extends from a region thereof corresponding to the side, to which the voltage or current is applied, in a direction opposite to the voltage or current application region.

10. The flexible substrate according to claim 4, wherein:
a voltage or current is applied to upper, lower, left, and right sides of the third substrate layer;
the plurality of first open portions of the first substrate layer have a uniform size and are disposed at a uniform density;
the plurality of second open portions of the third substrate layer have a uniform size and are disposed at a uniform density;
the size of the first open portions is smaller than the size of the second open portions;
a number of the plurality of first open portions is greater than a number of the plurality of second open portions;
the density of the plurality of first open portions is higher than the density of the plurality of second open portions; and
a density of the plurality of contact holes is varied in accordance with a voltage or current application direction.

11. The flexible substrate according to claim 10, wherein the density of the plurality of contact holes is gradually increased as the second substrate layer extends from regions thereof corresponding to the upper, lower, left, and right sides, to which the voltage or current is applied, toward a central region thereof.

12. The flexible substrate according to claim 4, wherein:
a voltage or current is applied to upper, lower, left, and right sides of the third substrate layer;
the plurality of contact holes are disposed at a uniform density;
the plurality of second open portions of the third substrate layer have a uniform size and are disposed at a uniform density;
a size of the first open portions is smaller than the size of the second open portions;
a number of the plurality of first open portions is greater than a number of the plurality of second open portions;
a density of the plurality of first open portions is higher than the density of the plurality of second open portions; and
the size of the plurality of first open portions and the line width of the first substrate layer between the plurality of first open portions are varied in accordance with a voltage or current application direction.

13. The flexible substrate according to claim 12, wherein:
the size of the plurality of first open portions is gradually decreased as the first substrate layer extends from regions thereof corresponding to the upper, lower, left, and right sides, to which the voltage or current is applied, toward a central region thereof;
the density of the plurality of first open portions is gradually increased as the first substrate layer extends from the regions thereof corresponding to the upper, lower, left, and right sides, to which the voltage or current is applied, toward the central region thereof; and
the line width of the first substrate layer between the plurality of first open portions is gradually decreased as the first substrate layer extends from the regions thereof corresponding to the upper, lower, left, and right sides, to which the voltage or current is applied, toward the central region thereof.

14. The flexible substrate according to claim 4, wherein:
each of the plurality of first open portions of the first substrate layer has a quadrangular ring shape;
the plurality of first open portions have different sizes, respectively, and smaller ones thereof are sequentially disposed inside an outermost one thereof having a largest size in such a manner that smaller ones thereof are disposed inside larger ones thereof;
the line width of the first substrate layer between the plurality of first open portions is uniform;
the plurality of second open portions of the third substrate layer have a uniform size and are disposed at a uniform density; and
a density of the plurality of contact holes is varied in accordance with a voltage or current application direction.

15. The flexible substrate according to claim 14, wherein:
a voltage or current is applied to upper, lower, left, and right sides of the third substrate layer; and
the density of the plurality of contact holes is gradually increased as the second substrate layer extends from regions thereof corresponding to the upper, lower, left, and right sides, to which the voltage or current is applied, toward a central region thereof.

16. The flexible substrate according to claim 4, wherein:
each of the plurality of first open portions of the first substrate layer has a quadrangular ring shape;
the plurality of first open portions have different sizes, respectively, and smaller ones thereof are sequentially disposed inside an outermost one thereof having a largest size in such a manner that smaller ones thereof are disposed inside larger ones thereof;
the plurality of contact holes are disposed at a uniform density;
the plurality of second open portions of the third substrate layer have a uniform size and are disposed at a uniform density; and
a size of the plurality of first open portions and the line width of the first substrate layer between the plurality of first open portions are varied in accordance with a voltage or current application direction.

17. The flexible substrate according to claim 16, wherein:
a voltage or current is applied to upper, lower, left, and right sides of the third substrate layer;
the size of the plurality of first open portions is gradually decreased as the first substrate layer extends from regions thereof corresponding to the upper, lower, left, and right sides, to which the voltage or current is applied, toward a central region thereof; and
the line width of the first substrate layer between the plurality of first open portions is gradually decreased as the first substrate layer extends from the regions thereof corresponding to the upper, lower, left, and right sides, to which the voltage or current is applied, toward the central region thereof.

18. A method of manufacturing a display apparatus, comprising:
forming a separation layer on a carrier substrate;
forming, on the separation layer, a first substrate layer made of a conductive material and having a plurality of first open portions;
forming, on the first substrate layer, a second substrate layer having a plurality of contact holes;
forming, on the second substrate layer, a third substrate layer electrically connected to the first substrate layer through the plurality of contact holes and made of a conductive material, the third substrate layer having a plurality of second open portions;
forming a fourth substrate layer on the third substrate layer;
sequentially forming, on the fourth substrate layer, a pixel layer with a thin film transistor and a light emitting diode and an encapsulation film; and
separating the carrier substrate by applying a voltage or current to the third substrate layer such that the first substrate layer generates heat.

19. The method according to claim 18, wherein:
the second substrate layer comprises a plastic material and an inorganic insulating layer;
the fourth substrate layer comprises a plastic material; and
each of the first substrate layer and the third substrate layer comprises a transparent electrode layer.

20. The method according to claim 18, wherein a resistance of the third substrate layer is smaller than a resistance of the first substrate layer, and
wherein a line width of the first substrate layer between the plurality of first open portions is narrower than a line width of the third substrate layer between the plurality of second open portions.
